(19) United States
(12) Patent Application Publication
(10) Pub. No.: US 2025/0212626 A1
(43) Pub. Date: Jun. 26, 2025

(54) DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Enjian YANG, Beijing (CN); Xing PENG, Beijing (CN); Liang GAO, Beijing (CN); Hao SUN, Beijing (CN); Wei CHEN, Beijing (CN); Ajuan DU, Beijing (CN); Xiaoxia HUANG, Beijing (CN); Yunhui HUANG, Beijing (CN); Feifan LI, Beijing (CN); Yongle WANG, Beijing (CN); Yiqian WU, Beijing (CN); Hufei YANG, Beijing (CN); Mengliang YAO, Beijing (CN); Guodong ZENG, Beijing (CN); Yilun ZENG, Beijing (CN)

(21) Appl. No.: 18/846,220

(22) PCT Filed: Sep. 26, 2023
(86) PCT No.: PCT/CN2023/121607

§ 371 Date: Sep. 11, 2024

(30) Foreign Application Priority Data
Oct. 31, 2022 (CN) 202211344097.9

(51) Int. Cl. H10K 59/131; H05K 1/18; H05K 9/00; H10K 59/80; H10K 102/00

(52) U.S. Cl. CPC H10K 59/131; H05K 1/189; H05K 9/0088; H10K 59/8794; H05K 2201/10128; H10K 2102/311

(57) ABSTRACT

A display device includes a display panel, a flexible circuit board, and a driving chip. The display panel includes a display area and a non-display area bent to the back of the display area. The driving chip is bonded and connected to the display panel in the non-display area. The flexible circuit board includes a bonding area bonded to the non-display area, and a first flat area, a bending area, and a second flat area arranged in sequence in a direction away from the bonding area. The flexible circuit board is at the back of the display area. The second flat area is between the first flat area and the display area. A first electromagnetic shielding layer is provided on at least a portion of the surface, close to the display area, of the second flat area.

### CROSS-REFERENCE TO RELATED APPLICATIONS

This disclosure is a national phase entry under 35 U.S.C. § 371 of International Application No. PCT/CN2023/121607 filed on Sep. 26, 2023, which claims priority to Chinese patent Application No. 202211344097.9, filed with the China National Intellectual Property Administration on Oct. 31, 2022 and entitled “Display Device and Manufacturing Method therefor”, the entire contents of which are incorporated herein by reference.

### TECHNICAL FIELD

The present disclosure relates to the field of display technology, and in particular to a display device.

### BACKGROUND

Flexible organic light emitting diodes (OLEDs) are bendable and are currently widely used in electronic products such as rigid mobile phones, foldable products, and wearable products. In order to elongate the battery life of an electronic product, the battery capacity needs to be increased, which requires more battery installation space. How to make more room for a battery within a limited space of the electronic product and increase capacity of the battery has become a technical problem that needs to be solved urgently.

### SUMMARY

A display device provided in embodiments of the present disclosure includes a display panel, a flexible circuit board, and a driving chip.

The display panel includes a display area and a non-display area bent to the back of the display area. The driving chip is bonded and connected to the display panel in the non-display area.

The flexible circuit board includes a bonding area bonded to the non-display area, and a first flat area, a bending area, and a second flat area arranged in sequence in a direction away from the bonding area. The flexible circuit board is located at the back of the display area. The second flat area is located between the first flat area and the display area. A first electromagnetic shielding layer is provided on at least a portion of a surface, close to the display area, of the second flat area.

In some embodiments of the present disclosure, the first flat area and the driving chip are located on different sides of the bonding area.

In some embodiments of the present disclosure, the first flat area and the driving chip are located on the same side of the bonding area.

In some embodiments of the present disclosure, the flexible circuit board is provided with an opening penetrating the second flat area along a direction from the first flat area to the second flat area. The opening is used to accommodate the driving chip. The first electromagnetic shielding layer is arranged around the driving chip.

In some embodiments of the present disclosure, the flexible circuit board includes a base layer; a first conductive layer, a first covering film and a shielding film arranged in sequence on a first surface of the base layer; and a second conductive layer and a second covering film arranged in sequence on a second surface of the base layer. The second conductive layer is bonded and connected to the display panel. A portion of the shielding film in the second flat area is reused as the first electromagnetic shielding layer.

In some embodiments of the present disclosure, a second electromagnetic shielding layer is provided on at least a portion of a surface of the first flat area facing away from the display area. A portion of the shielding film in the first flat area is reused as the second electromagnetic shielding layer.

In some embodiments of the present disclosure, the thickness of the bending area is smaller than the thickness of the first flat area, and smaller than the thickness of the second flat area.

In some embodiments of the present disclosure, the shielding film, the first conductive layer and the second conductive layer are hollowed out in the bending area.

In some embodiments of the present disclosure, a heat dissipation structure is further included at the back of the display area. The flexible circuit board is arranged on a side of the heat dissipation structure away from the display area.

In some embodiments of the present disclosure, the display device further includes a first adhesive between the first flat area and the second flat area, and a second adhesive on a surface, close to the display area, of the first electromagnetic shielding layer.

In some embodiments of the present disclosure, when the first flat area and the driving chip are located on different sides of the bonding area, the flexible circuit board is fixedly connected to a surface the heat dissipation structure away from the display area through the second adhesive.

In some embodiments of the present disclosure, when the first flat area and the driving chip are located on the same side of the bonding area, the flexible circuit board is fixedly connected to a surface of the non-display area facing away from the display area through the second adhesive.

### BRIEF DESCRIPTION OF FIGURES

FIG. 1 is a schematic diagram of a structure of a flexible OLED display module in the related art.

FIG. 2 is a schematic diagram of a structure of a display device provided in an embodiment of the present disclosure.

FIG. 3 is a schematic diagram of a structure of a display device provided in an embodiment of the present disclosure.

FIG. 4 is a schematic diagram of a structure of a display device provided in an embodiment of the present disclosure.

FIG. 5 is an enlarged schematic diagram of a structure in the area Q in FIG. 2.

FIG. 6 is a schematic diagram of a structure of a display device provided in an embodiment of the present disclosure.

FIG. 7 is a schematic diagram of a structure of a display device provided in an embodiment of the present disclosure.

FIG. 8 is a schematic diagram of a structure of a display device provided in an embodiment of the present disclosure.

FIG. 9 is a schematic diagram of a structure of a display device provided in an embodiment of the present disclosure.

FIG. 10 is a flow chart of a method for manufacturing a display device provided in an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments. Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The words “include” or “comprise” and the like used in this disclosure mean that the elements or objects preceding the words include the elements or objects listed after the words and their equivalents, but do not exclude other elements or objects.

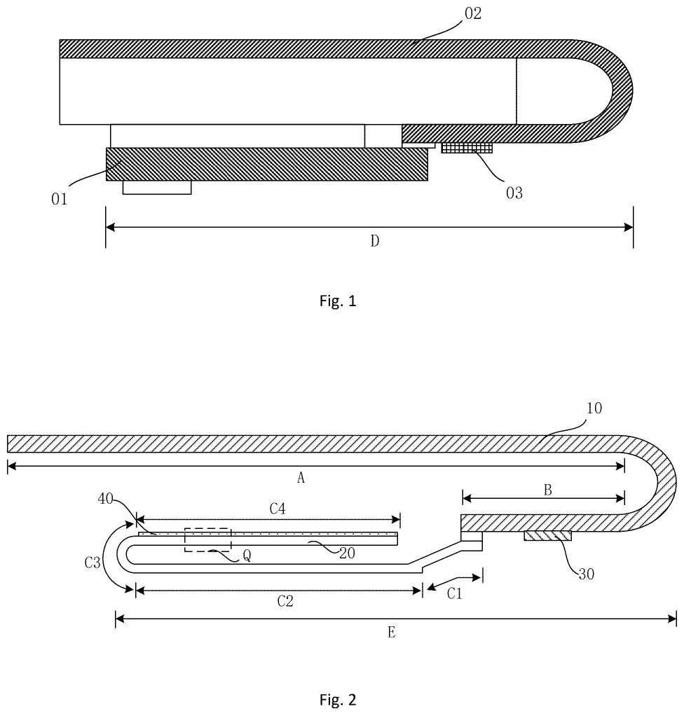

In the related art, in order to free up more space for the battery, it is necessary to minimize the thickness of the display module and the length of the MFPC (Main Flexible Printed Circuit) 01 extending along the mainboard. Taking the flexible OLED display module shown in FIG. 1 as an example, after bonding the MFPC 01 to the panel 02, on the one hand, the distance value (as shown by D in FIG. 1) from the non-bonding side of the MFPC 01 to the bottom border of the display module is relatively large. The distance value generally includes the extending length of the MFPC 01, the safety distance between the bonding side of the MFPC 01 and the integrated circuit (IC) chip 03 bonded to the panel 02, the width of the IC chip 03 and the width of the bottom border of the display module, thereby occupying the space of the entire machine. On the other hand, the IC chip 03 is exposed to the outside and is susceptible to external interference, thereby affecting the working performance of the display module.

In view of this, embodiments of the present disclosure provide a display device for saving the space of the entire device while taking into account the electromagnetic protection effect.

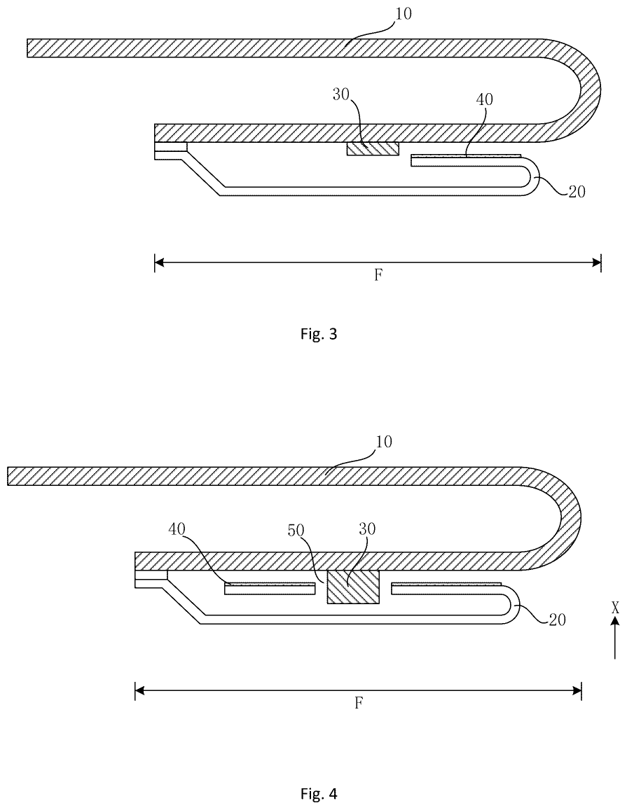

As shown in FIG. 2 and FIG. 3, embodiments of the present disclosure provide a display device.

The display device includes a display panel 10, a flexible circuit board 20 and a driving chip 30.

The display panel 10 includes a display area A and a non-display area B bent to the back of the display area A. The driving chip 30 is bonded and connected to the flexible circuit board 20 in the non-display area B.

The flexible circuit board 20 includes a bonding area C1 bonded to the non-display area B, and a first flat area C2, a bending area C3 and a second flat area C4 arranged in sequence along a direction away from the bonding area C1. The flexible circuit board 20 is located at the back of the display area A. The second flat area C4 is located between the first flat area C2 and the display area A. A first electromagnetic shielding layer 40 is provided on at least a portion of the surface, close to the display area A, of the second flat area C4.

In some embodiments, the display panel 10 includes a display area A and a non-display area B bent to the back of the display area A. A distribution of the display area A and the non-display area B may be as shown in FIG. 2. In addition, the driving chip 30 is bonded and connected to the display panel 10 in the non-display area B. For example, the driving chip 30 is bonded and connected to a surface, facing away from the display area A, of the non-display area B of the display panel 10. Moreover, the flexible circuit board 20 includes a bonding area C1 bonded to the non-display area B, and a first flat area C2, a bending area C3, and a second flat area C4 sequentially arranged in a direction away from the bonding area C1. A distribution of the bonding area C1, the first flat area C2, the bending area C3, and the second flat area C4 is shown in FIG. 2. Further, the distribution of the display area A, the non-display area B, the bonding area C1, the first flat area C2, the bending area C3 and the second flat area C4 may also be set according to actual application needs, which is not limited here.

Still referring to FIG. 2 and FIG. 3, the flexible circuit board 20 is located at the back of the display area A. For example, the flexible circuit board 20 is bonded and connected to the side of the non-display area B away from the display area A through the bonding area C1, thereby ensuring the electrical connection between the display panel 10 and the flexible circuit board 20. In some exemplary embodiments, the display panel 10 and the flexible circuit board 20 may be connected together through one of a board to board (BTB) connector, a zero insertion force (ZIF) connector, and a FOF bonding. In some exemplary embodiments, the electrical connection between the display panel 10 and the flexible circuit board 20 may be achieved by using a solder contact pad connection method. Further, the connection method between the display panel 10 and the flexible circuit board 20 may also be set according to actual application needs, which is not limited here.

In some embodiments, the flexible circuit board 20 may be bent at an appropriate position. After being bent, the second flat area C4 of the flexible circuit board 20 is located between the first flat area C2 and the display area A. Compared with FIG. 1, the flexible circuit board 20 of the display device in embodiments of the present disclosure is folded back to the back of the display area A, thereby reducing the distance between the outer boundary of the flexible circuit board 20 away from the non-display area B and the bottom border of the display panel 10, saving the overall space of the display device and providing the possibility of installing a large-capacity battery. In addition, at least a portion of a surface, close to the display region A, of the second flat area C4 is provided with a first electromagnetic shielding layer 40. In some exemplary embodiments, the first electromagnetic shielding layer 40 may be disposed on the entire surface, close to the display region A, of the second flat area C4. In some exemplary embodiments, the first electromagnetic shielding layer 40 may be disposed on a partial area of the surface, close to the display area A, of the second flat area C4. In this way, the first electromagnetic shielding layer 40 effectively avoids interference from external electromagnetic signals, improves the electrostatic protection capability of the display device, and ensures the performance of the display device. In this way, the space of the whole machine can be saved while the electromagnetic protection effect can be taken into account.

In some embodiments of the present disclosure, the driving chip 30 and the flexible circuit board 20 may be arranged in the following manner. In some exemplary embodiments, the first flat area C2 and the driving chip 30 are located on different sides of the bonding area C1.

Still referring to FIG. 2, in an exemplary embodiment, the first flat area C2 and the driving chip 30 are located on different sides of the bonding area C1. The display panel 10 and the flexible circuit board 20 may be bonded together by forward bonding. In an exemplary embodiment, the distance from the outer boundary of the flexible circuit board 20 away from the non-display area B to the bottom border of the display panel 10 is shown as E in FIG. 2. Under the premise that the relevant structural parameters of each component in the display device in FIG. 2 are the same as those in FIG. 1, E is obviously smaller than D, thereby saving the overall space of the display device and providing the possibility of installing a large-capacity battery.

In some exemplary embodiments, the first flat area C2 and the driving chip 30 are located on the same side of the bonding area C1.

Still referring to FIG. 3, in an exemplary embodiment, the first flat area C2 and the driving chip 30 are located on the same side of the bonding area C1. The display panel 10 and the flexible circuit board 20 may be bonded together by reverse bonding. In the exemplary embodiment, the distance from the outer boundary of the flexible circuit board 20 away from the non-display area B to the bottom border of the display panel 10 is shown as F in FIG. 3. Under the premise that the relevant structural parameters of each component in the display device in FIG. 3 are the same as those in FIG. 1 or FIG. 2, F is obviously smaller than D, and F is also smaller than E, which further saves the overall space of the display device and provides the possibility of installing a large-capacity battery.

It should be noted that, in addition to the manners shown in FIG. 2 and FIG. 3, the driving chip 30 and the flexible circuit board 20 may be arranged in other manners according to actual application requirements, which are not limited here.

In some embodiments of the present disclosure, the flexible circuit board 20 is provided with an opening 50 that passes through the second flat area C4 along the direction from the first flat area C2 to the second flat area C4. The opening 50 is for accommodating the driving chip 30. The first electromagnetic shielding layer 40 is arranged around the driving chip 30.

As shown in FIG. 4, the direction indicated by the arrow X is the direction from the first flat area C2 to the second flat area C4. Correspondingly, along the direction indicated by the arrow X, the flexible circuit board 20 is provided with an opening 50 penetrating the second flat area C4. The opening 50 is for accommodating the driving chip 30. The first electromagnetic shielding layer 40 is disposed around the driving chip 30. In some exemplary embodiments, the region where the driving chip 30 and the flexible circuit board 20 overlap can be avoided. In this way, on one hand, the driving chip 30 is effectively avoided through the opening 50 on the flexible circuit board 20, thereby preventing the driving chip 30 from being damaged by physical collision, thereby ensuring the performance of the display device.

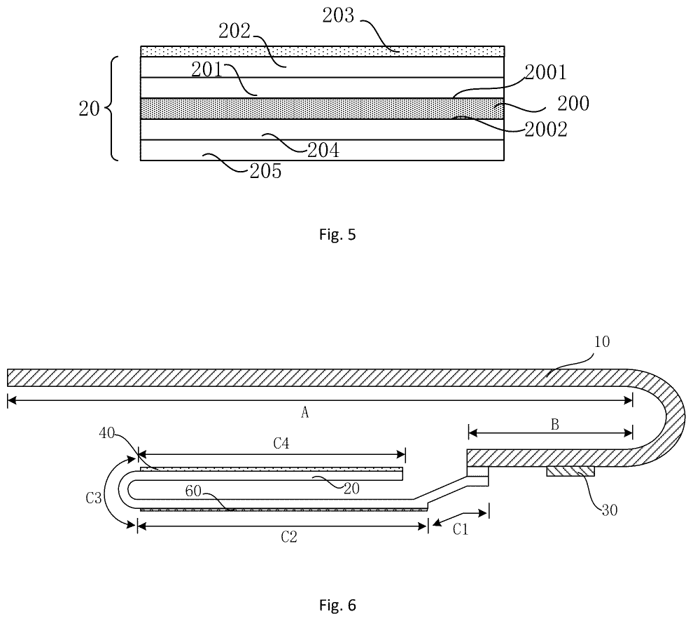

In some embodiments of the present disclosure, FIG. 5 is an enlarged schematic diagram of the structure of the area Q in FIG. 2. In some exemplary embodiments, the flexible circuit board 20 may be a two-layer board, thereby reducing the manufacturing cost of the flexible circuit board 20 while ensuring the bending performance of the flexible circuit board 20. In some exemplary embodiments, still in combination with FIG. 5, the flexible circuit board 20 includes a base layer 200, a first conductive layer 201, a first covering film 202 and a shielding film 203 arranged in sequence on the first surface 2001 of the base layer 200, and a second conductive layer 204 and a second covering film 205 arranged in sequence on the second surface 2002 of the base layer 200. The second conductive layer 204 is bonded and connected to the display panel 10. A portion of the shielding film 203 located in the second flat area C4 is reused as the first electromagnetic shielding layer 40.

In some embodiments, the flexible circuit board 20 includes a base layer 200. The material of the base layer 200 may be polyimide (PI) or polyethylene terephthalate (PET). Further, the material of the base layer 200 may also be set according to actual application needs, which is not limited here. In addition, the flexible circuit board 20 further includes a first conductive layer 201, a first covering film 202 and a shielding film 203 sequentially arranged on a first surface 2001 of the base layer 200, and a second conductive layer 204 and a second covering film 205 sequentially arranged on a second surface 2002 of the base layer 200. The shielding film 203 may be one or more of conductive rubber, conductive cloth, conductive foam and conductive shielding glue. Further, the shielding film 203 may be provided according to actual application requirements, which is not limited here.

In some exemplary embodiments, the material of the first conductive layer 201 and the second conductive layer 204 may be copper foil. In an implementation, the copper foil may be etched according to the arrangement of the required signal lines, which will not be described in detail here. In addition, the first covering film 202 can prevent the first conductive layer 201 from being exposed to the air, thereby preventing the first conductive layer 201 from being corroded by water and oxygen. The second covering film 205 can prevent the second conductive layer 204 from being exposed to the air, thereby preventing the second conductive layer 204 from being corroded by water and oxygen, thereby ensuring the performance of the display device.

Still combining with the exemplary embodiments shown in FIGS. 2 and 5, the second conductive layer 204 is bonded and connected to the display panel 10. The portion of the shielding film 203 in the second flat area C4 may be reused as the first electromagnetic shielding layer 40. In this way, while preparing the flexible circuit board 20, the required first electromagnetic shielding layer 40 may also be prepared, thereby realizing the integration of the electromagnetic protection function of the flexible circuit board 20, thus reducing the manufacturing cost of the display device while taking into account the electrostatic protection performance of the flexible circuit board 20.

In some embodiments of the present disclosure, as shown in FIG. 6, a second electromagnetic shielding layer 60 is provided on at least a portion of the surface of the first flat area C2 facing away from the display area A. A portion of the shielding film 203 in the first flat area C2 is reused as the second electromagnetic shielding layer 60. In this way, the required second electromagnetic shielding layer 60 is prepared while the flexible circuit board 20 is prepared, thereby realizing the integration of the electromagnetic protection function of the flexible circuit board 20, thus reducing the manufacturing cost of the display device while taking into account the electrostatic protection performance of the flexible circuit board 20.

In some exemplary embodiments, the thickness of the bending area C3 is smaller than the thickness of the first flat area C2, and smaller than the thickness of the second flat area C4. For example, the flexible circuit board 20 is provided with only the first conductive layer 201 in the bending area C3. For another example, the flexible circuit board 20 is provided with two film layers including the first conductive layer 201 and the second conductive layer 204 in the first flat area C2. For another example, the flexible circuit board 20 is provided with two film layers including the first conductive layer 201 and the second conductive layer 204 in the second flat area C4. Further, the film layers of the bending area C3, the first flat area C2 and the second flat area C4 may also be set according to actual application requirements, which is not limited here.

In some exemplary embodiments, the shielding film 203, the first conductive layer 201 and the second conductive layer 204 are hollowed out in the bending area C3. The corresponding schematic diagram may be as shown in FIG. 6, thereby improving the bending performance of the flexible circuit board 20. In some exemplary embodiments, the shielding film 203, the first conductive layer 201, and the second conductive layer 204 are all hollowed out in the bending area C3, which further improves the bending performance of the flexible circuit board 20.

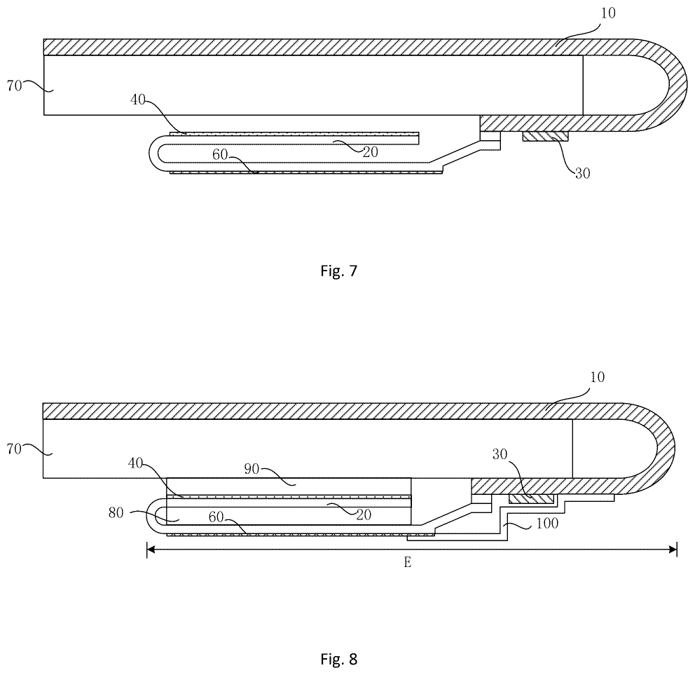

In some embodiments of the present disclosure, as shown in FIG. 7, the display device further includes a heat dissipation structure 70 at the back of the display area A. The flexible circuit board 20 is arranged on a side of the heat dissipation structure 70 away from the display area A.

Still referring to FIG. 7, the display device further includes a heat dissipation structure 70 located at the back of the display area A, thereby ensuring the heat dissipation performance of the display device. In some exemplary embodiments, the heat dissipation structure 70 includes embroidery glue (EMBO), foam (FOAM) and a copper (Cu) foil, etc., which are sequentially stacked on the back of the display area A. In addition, in order to ensure the bonding effect between the film layers of the heat dissipation structure 70, the heat dissipation structure 70 further includes a glue layer disposed on the opposite side surfaces of the embroidery glue, and a glue layer disposed between the foam and the copper foil. In this way, the heat dissipation structure 70 may block light, prevent light leakage, and shield the influence of related signals on the noise of the flexible circuit board 20, thereby improving the performance of the display device.

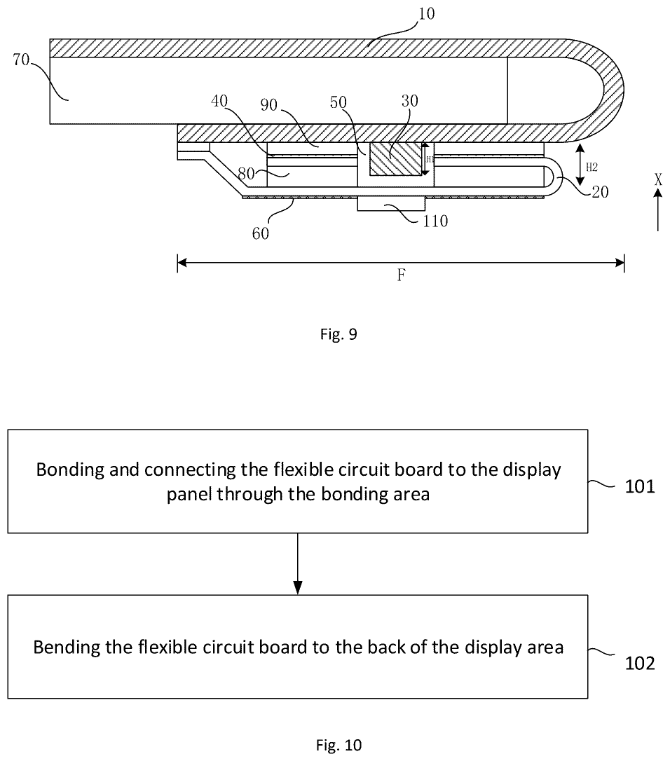

In some embodiments of the present disclosure, as shown in FIG. 8 and FIG. 9, the display device further includes a first adhesive 80 between the first flat area C2 and the second flat area C4, and a second adhesive 90 on the surface of the flexible circuit board 20 close to the display area A.

In some exemplary embodiments, still in combination with FIG. 8, when the first flat area C2 and the driving chip 30 are located on different sides of the bonding area C1, the flexible circuit board 20 is fixedly connected to the surface of the heat dissipation structure 70 away from the display area A through the second adhesive 90. In this way, the structural stability between the display panel 10 and the flexible circuit board 20 is ensured. In addition, still in combination with FIG. 8, the display device provided by the embodiments of the present disclosure also includes a cover tape 100 (Cover Tape) arranged at the side of the driving chip 30 away from the display area. One end of the cover tape 100 is in contact with the non-display area B, and the other end of the cover tape 100 is in contact with the first flat area C2. The orthographic projection of the driving chip 30 on the display area A completely falls within the orthographic projection of the cover tape 100 on the display area A. The cover tape 100 is used to shield the interference of external electromagnetic signals on the driving chip 30, thereby ensuring the working performance of the driving chip 30 and improving the performance of the display device. It should be noted that, in the actual process of manufacturing the display device shown in FIG. 8, the cover tape 100 may be separately provided according to the position of the driving chip 30.

In some exemplary embodiments, still in combination with FIG. 9, when the first flat area C2 and the driving chip 30 are located on the same side of the bonding area C1, the flexible circuit board 20 is fixedly connected to the surface of the non-display area B away from the display area A through the second adhesive 90. In this way, the structural stability between the display panel 10 and the flexible circuit board 20 is ensured.

In some embodiments of the present disclosure, still in combination with FIG. 9, the display device further includes at least one component 110 disposed on a surface of the first flat area C2 facing away from the display area A. The at least one component 110 may be at least one of a resistor, a capacitor, an inductor, etc. The at least one component 110 may be set according to actual application needs, which is not limited here.

It should be noted that in the exemplary embodiment shown in FIG. 9, the first electromagnetic shielding layer 40 is arranged around the driving chip 30. The display device shown in FIG. 9 does not need to separately set a covering tape 100 compared to the display device shown in FIG. 8. The shielding film 203 of the flexible circuit board 20 may be directly reused as the covering tape 100. While simplifying the manufacturing process, it saves the space of the entire machine and improves the protection capability of the display device.

In some embodiments, still in combination with FIG. 9, along the direction from the first flat area C2 to the display area A, the total thickness of the first adhesive 80, the second flat area C4, the first electromagnetic shielding layer 40 and the second adhesive 90 is greater than the height of the driving chip 30. The depth of the opening 50 is greater than the height of the driving chip 30. Still taking the exemplary embodiment shown in FIG. 9 as an example, the height of the driving chip 30 is H1. The depth of the opening 50 is H2. H2 is greater than H1. In this way, the driving chip 30 is effectively avoided via the opening 50 which saves space in the thickness direction of the display device, thereby ensuring a thin design of the display device. Further, the thicknesses of the first adhesive 80, the second flat area C4, the first electromagnetic shielding layer 40, and the second adhesive 90 may be set according to the height of the driving chip 30 in actual applications, and are not limited here.

In the process of manufacturing the flexible circuit board 20 provided in the embodiments of the present disclosure, the first adhesive 80 may be pre-bonded to the first flat area C2, and the second adhesive 90 may be pre-bonded to the first electromagnetic shielding layer 40 in the second flat area C4. Then, the second flat area C4 is bent along the bending area C3 to the back of the first flat area C2. After that, the flexible circuit board 20 with the desired bent shape is formed. In an actual manufacturing process, the display panel 10 and the flexible circuit board 20 may be manufactured separately, thereby improving the manufacturing efficiency of the display device. Then, the bent flexible circuit board 20 is bonded and connected to the display panel 10. Then the bonded flexible circuit board 20 is bent to the back of the display panel 10, so as to obtain the desired display device.

It should be noted that, in addition to the film layers mentioned above, the display device provided in embodiments of the present disclosure may also include other film layer structures. The other film layer structures may be arranged with reference to related technologies and will not be described in detail here. In addition, the display device provided in embodiments of the present disclosure may be an OLED flexible display device, and the corresponding product may be any product or component with a display function, such as a mobile phone, a tablet computer, a television, a monitor, a laptop computer, a digital photo frame, a navigator, etc. The other essential components of the display device should be understood by those of ordinary skill in the art and will not be elaborated here, nor should they be regarded as limitations for the present disclosure.

Based on the same disclosed concept, as shown in FIG. 10, embodiments of the present disclosure further provide a method for manufacturing the display device as described above. The manufacturing method includes:

S101: Bonding and connecting the flexible circuit board to the display panel through the bonding area;

S102: Bending the flexible circuit board to the back of the display area.

In some exemplary embodiments, the implementation process of operations S101 and S102 may include: first, preparing patterns of film layers of the display panel 10 in the display area A and the non-display area B using relevant manufacturing processes, and preparing patterns of film layers of the flexible circuit board 20 in each area; then, bonding and connecting the flexible circuit board 20 to the display panel 10 through the bonding area C1; and then, bending the flexible circuit board 20 to the back of the display area A.

It should be noted that when preparing the display device shown in FIG. 9, an opening 50 penetrating the second flat area C4 of the flexible circuit board 20 should be prepared in advance in so as to avoid the driving chip 30. The relevant preparation process will not be described in detail.

The display device provided in embodiments of the present disclosure includes a display panel 10, a flexible circuit board 20 and a driving chip 30. The display panel 10 includes a display area A and a non-display area B bent to the back of the display area A. The driving chip 30 is bonded and connected to the display panel 10 in the non-display area B. The flexible circuit board 20 includes a bonding area C1 bonded to the non-display area B, and a first flat area C2, a bending area C3 and a second flat area C4 arranged in sequence along a direction away from the bonding area C1. The flexible circuit board 20 is located at the back of the display area A. The second flat area C4 is located between the first flat area C2 and the display area A. That is to say, the folded flexible circuit board 20 is arranged at the back of the display area A, thereby reducing the distance between the outer boundary of the flexible circuit board 20 away from the non-display area B and the bottom border of the display panel 10, saving the overall space of the display device and providing the possibility of installing a large-capacity battery. In addition, at least a portion of a surface, close to the display region A, of the second flat area C4 is provided with a first electromagnetic shielding layer 40. In this way, the first electromagnetic shielding layer 40 effectively avoids interference from external electromagnetic signals, which improves the electrostatic protection capability of the display device, and ensures the performance of the display device. In this way, the space of the whole machine can be saved while the electromagnetic protection effect can be taken into account.

Although preferred embodiments of the present disclosure have been described, additional changes and modifications may be made to these embodiments once those skilled in the art are aware of the basic inventive concepts. Therefore, it is intended that the appended claims be interpreted as including the preferred embodiment as well as all changes and modifications that fall within the scope of the present disclosure.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalents, the present disclosure is intended to include these modifications and variations.

What is claimed is:

1. A display device, comprising:
a display panel,
a flexible circuit board, and
a driving chip;
wherein the display panel comprises:
a display area, and
a non-display area bent to a back of the display area;
wherein the driving chip is bonded and connected to the non-display area of the display panel;
the flexible circuit board comprises:
a bonding area bonded to the non-display area, and
a first flat area, a bending area, and a second flat area arranged in sequence in a direction away from the bonding area;
wherein the flexible circuit board is at the back of the display area, the second flat area is between the first flat area and the display area, and a first electromagnetic shielding layer is provided on at least a portion of a surface, close to the display area, of the second flat area.

2. The display device according to claim 1, wherein the first flat area and the driving chip are on different sides of the bonding area.

3. The display device according to claim 1, wherein the first flat area and the driving chip are on a same side of the bonding area.

4. The display device according to claim 3, wherein:
along a direction from the first flat area to the second flat area, the flexible circuit board is provided with an opening penetrating the second flat area;
the opening is for accommodating the driving chip; and
the first electromagnetic shielding layer is arranged around the driving chip.

5. The display device according to claim 1, wherein the flexible circuit board comprises:
a base layer,
a first conductive layer, a first covering film, and a shielding film sequentially arranged on a first surface of the base layer, and
a second conductive layer and a second covering film sequentially arranged on a second surface of the base layer;
wherein the second conductive layer is bonded and connected to the display panel, and a portion, in the second flat area, of the shielding film is reused as the first electromagnetic shielding layer.

6. The display device according to claim 5, wherein:
a second electromagnetic shielding layer is provided on at least a portion of a surface, facing away from the display area, of the first flat area; and
a portion, in the first flat area, of the shielding film is reused as the second electromagnetic shielding layer.

7. The display device according to claim 6, wherein a thickness of the bending area is smaller than a thickness of the first flat area, and smaller than a thickness of the second flat area.

8. The display device according to claim 6, wherein the shielding film, the first conductive layer and the second conductive layer are hollowed out in the bending area.

9. The display device according to claim 6, further comprising:
a heat dissipation structure at the back of the display area;
wherein the flexible circuit board is arranged at a side of the heat dissipation structure away from the display area.

10. The display device according to claim 9, further comprising:
a first adhesive between the first flat area and the second flat area, and
a second adhesive on a surface, close to the display area, of the first electromagnetic shielding layer.

11. The display device according to claim 10, wherein the first flat area and the driving chip are on different sides of the bonding area, and the flexible circuit board is fixedly connected to a surface, facing away from the display area, of the heat dissipation structure through the second adhesive.

12. The display device according to claim 10, wherein the first flat area and the driving chip are located on a same side of the bonding area, and the flexible circuit board is fixedly connected to a surface, facing away from the display area, of the non-display area through the second adhesive.
